(19) United States
(12) Patent Application Publication
(10) Pub. No.: US 2026/0304785 A1
(43) Pub. Date: Oct. 1, 2026

(54) SEMICONDUCTOR DEVICE AND METHOD OF MANUFACTURING SEMICONDUCTOR DEVICE

(71) Applicant: SK hynix Inc., Icheon-si (KR)

(72) Inventors: Jeong Hoon BAE, Icheon-si (KR); Jeong Ho Yeon, Icheon-si (KR)

(21) Appl. No.: 19/294,920

(22) Filed: Aug. 8, 2025

(30) Foreign Application Priority Data
Mar. 27, 2025 (KR) 10-2025-0039536

(51) Int. Cl. H10B 63/00; G11C 5/06; H10B 61/00; H10B 63/10; H10N 50/10; H10N 70/00; H10N 70/20

(52) U.S. Cl. CPC H10B 63/20; G11C 5/063; H10B 63/80; H10N 70/063; H10N 70/826; H10B 61/10; H10B 63/10; H10N 50/10; H10N 70/231

(57) ABSTRACT

A semiconductor device includes row lines extending in a first direction, column lines positioned on the row lines, and extending in a second direction that crosses the first direction, and memory cells positioned between the row lines and the column lines, respectively, and spaced apart from each other by a first interval in the first direction and spaced apart from each other by a second interval in the second direction. The second interval is shorter than the first interval.

### CROSS-REFERENCE TO RELATED APPLICATION

This application claims priority under 35 U.S.C. § 119 to Korean Patent Application No. 10-2025-0039536 filed on Mar. 27, 2025, which is incorporated herein by reference in its entirety.

### BACKGROUND

### 1. Technical Field

The present disclosure relates to an electronic device and a method of manufacturing the electronic device, and more particularly, to a semiconductor device and a method of manufacturing the semiconductor device.

### 2. Related Art

An integration degree of a semiconductor device is mainly determined by an area occupied by a unit memory cell. Recently, as improvement in an integration degree of a semiconductor device in which a memory cell is formed as a single layer on a substrate reaches a limit, a three-dimensional semiconductor device in which memory cells are stacked on a substrate is being proposed. In addition, various structures and manufacturing methods are being developed in order to improve operation reliability of the semiconductor device.

### SUMMARY

According to an embodiment of the present disclosure, a semiconductor device may include row lines extending in a first direction, column lines positioned on the row lines, and extending in a second direction that crosses the first direction, and memory cells positioned between the row lines and the column lines, respectively, and spaced apart from each other by a first interval in the first direction and spaced apart from each other by a second interval in the second direction, the second interval being shorter than the first interval.

According to an embodiment of the present disclosure, a semiconductor device may include row lines extending in a first direction, memory cells positioned on the row lines, barrier patterns positioned on the memory cells, respectively, and column lines extending in a second direction that crosses the first direction, and connecting the barrier patterns, and the memory cells may be spaced apart from each other by a first interval in the first direction and spaced apart from each other by a second interval in the second direction, the second interval being shorter than the first interval.

According to an embodiment of the present disclosure, a method of manufacturing a semiconductor device may include forming a memory layer on a first conductive layer, forming memory lines that extend in a first direction and are spaced apart from each other by a second interval in a second direction by etching the memory layer, the second direction crossing the first direction, forming row lines that extend in the first direction by etching the first conductive layer, forming memory cells arranged in the first direction and the second direction and spaced apart from each other by a first interval in the first direction by etching the memory lines, the first interval being greater than the second interval, and forming column lines extending in the second direction on the memory cells.

### BRIEF DESCRIPTION OF THE DRAWINGS

FIGS. 1A, 1B, and 1C are drawings illustrating a semiconductor device according to an embodiment of the present disclosure.

FIGS. 2A, 2B, 3A, 3B, 4A, 4B, 5A, 5B, 5C, 6A, 6B, 6C, 7A, 7B, and 7C are drawings illustrating a method of manufacturing a semiconductor device according to an embodiment of the present disclosure.

### DETAILED DESCRIPTION

Embodiments of the present disclosure provides a semiconductor device and a method of manufacturing the semiconductor device having a stable structure and an improved characteristic.

According to the present technology, a semiconductor device having a stable structure and improved reliability may be provided. As used herein, including in the claims, the term ‘or’ in a list of items (e.g., a list introduced by phrases such as ‘at least one of,’ ‘one or more of,’ or ‘one or both of’) is intended to be inclusive unless explicitly stated otherwise. Specifically, the term ‘or’ should be interpreted to cover any individual item in the list, any combination of items in the list, or all items in the list. For example, a phrase such as ‘at least one of A, B, or C’ is intended to encompass A alone, B alone, C alone, any combination of A and B, A and C, or B and C, as well as A, B, and C together. This inclusive interpretation applies unless an explicit indication to the contrary is provided in a particular context. Moreover, a first element “on” a second element indicates that the first element can be “directly on” the second element, or that at least one intervening element can be interposed between the first and second elements.

Hereinafter, some embodiments according to the technical spirit of the present disclosure are described with reference to the accompanying drawings.

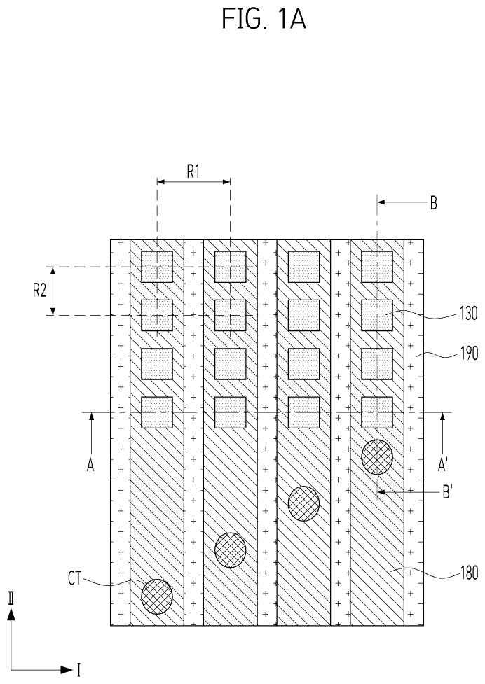

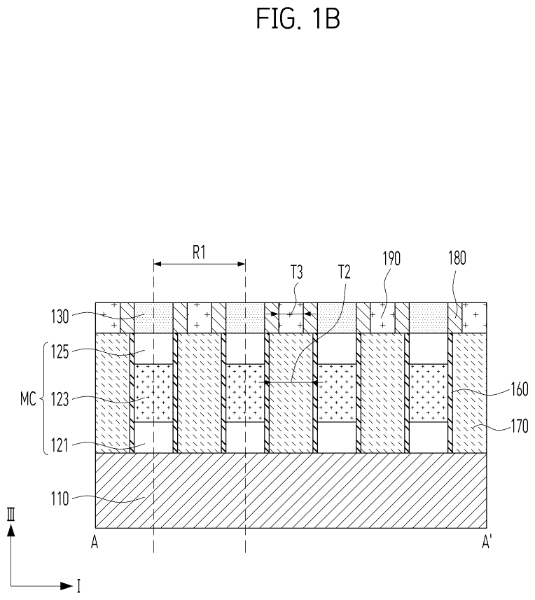

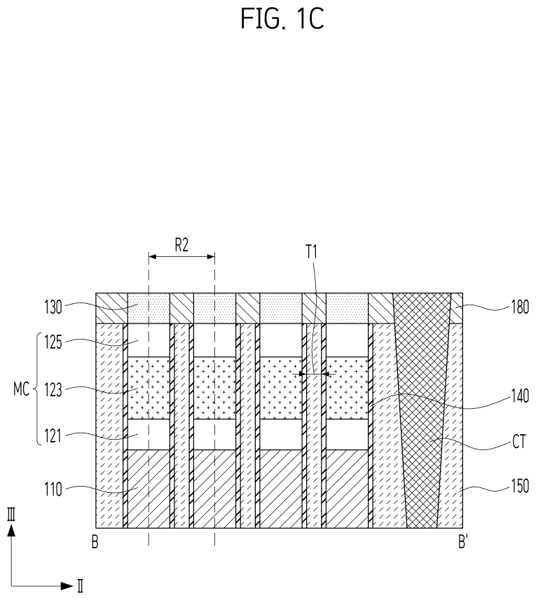

FIGS. 1A, 1B, and 1C are drawings illustrating a semiconductor device according to an embodiment of the present disclosure. FIG. 1A is a plan view, FIG. 1B is a cross-sectional view along line A-A′ of FIG. 1A, and FIG. 1C is a cross-sectional view along line B-B′ of FIG. 1A.

Referring to FIGS. 1A to 1C, the semiconductor device may include row lines 110, memory cells MC, barrier patterns 130, and column lines 180. The semiconductor device may further include first liner patterns 140, first gap-fill patterns 150, second liner patterns 160, second gap-fill patterns 170, third gap-fill patterns 190, and contact vias CT.

The row lines 110 may extend in a first direction I. The column lines 180 may cross the row lines 110, and may be positioned on the row lines 110. The column lines 180 may extend in a second direction II crossing the first direction I. As an example, each of the row lines 110 may be a word line, and each of the column lines 180 may be a bit line. As another example, each of the row lines 110 may be a bit line, and each of the column lines 180 may be a word line. Here, the row lines 110 and the column lines 180 may include a conductive material such as tungsten.

The memory cells MC may be positioned between the row lines 110 and the column lines 180, respectively. Each of the memory cells MC may include a lower electrode pattern 121, a variable resistance pattern 123, and an upper electrode pattern 125.

The lower electrode pattern 121 may be positioned on the row line 110. The lower electrode pattern 121 may be a portion of the row line 110, or may be electrically connected to the row line 110. The upper electrode pattern 125 may be positioned on the lower electrode pattern 121. The upper electrode pattern 125 may be a portion of the column line 180, or may be electrically connected to the column line 180. The variable resistance pattern 123 may be positioned between the lower electrode pattern 121 and the upper electrode pattern 125.

At least one of the lower electrode pattern 121 or the upper electrode pattern 125 may include polysilicon, tungsten (W), tungsten nitride (WNx), tungsten silicide (WSix), titanium (Ti), titanium nitride (TiNx), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SiC), silicon carbon nitride (SiCN), copper (Cu), zinc (Zn), nickel (Ni), cobalt (Co), lead (Pb), platinum (Pt), molybdenum (Mo), ruthenium (Ru), or the like, or may include a combination thereof.

The variable resistance pattern 123 may be used as a data storage and a selection element simultaneously. The variable resistance pattern 123 may include a resistive material, and may have a characteristic of reversibly changing between different resistance states according to an applied voltage or current.

The variable resistance pattern 123 may maintain an amorphous state during a program operation, and may not change to a crystalline state after the program operation. In other words, a phase of the variable resistance pattern 123 may not change after the program operation. For example, the variable resistance pattern 123 may include a variable resistance material of which a resistance changes without a phase change, and may include a chalcogenide element. The variable resistance pattern 123 may include germanium (Ge), antimony (Sb), arsenic (As), silicon (Si), indium (In), tin (Sn), gallium (Ga), or the like, or may include a combination thereof.

The variable resistance pattern 123 may include a phase change material, and may include a chalcogenide. The variable resistance pattern 123 may include chalcogenide glass, chalcogenide alloy, or the like. The variable resistance pattern 123 may change phase according to a program operation. For example, the variable resistance pattern 123 may have a low resistance crystalline state by a set operation. In addition, the variable resistance pattern 123 may have a high resistance amorphous state by a reset operation. Therefore, the variable resistance pattern 123 may store data in the memory cell MC by using a resistance difference according to the phase.

The variable resistance pattern 123 may include a metal oxide (transition metal oxide), or may include a metal oxide such as a perovskite material. Therefore, data may be stored in the memory cell MC by generating or disappearing an electrical path in the variable resistance pattern 123.

The variable resistance pattern 123 may have an MTJ structure, and may include a magnetization fix layer, a magnetization free layer, and a tunnel barrier layer interposed therebetween. For example, the magnetization fix layer and the magnetization free layer may include a magnetic material, and the tunnel barrier layer may include an oxide such as magnesium (Mg), aluminum (Al), zinc (Zn), or titanium (Ti). Here, a magnetization direction of the magnetization free layer may be changed by spin torque of electrons in the applied current. Therefore, data may be stored in the memory cell MC according to a magnetization direction change of the magnetization free layer with respect to the magnetization direction of the magnetization fix layer.

In addition, the variable resistance pattern 123 may have a metal insulator metal (MIM) structure including a metal oxide. In this case, data may be stored in the memory cell MC or a second memory cell MC2 by using a resistance change of the metal oxide that occurs by applying a short electric pulse.

For reference, although not shown in this drawing, the semiconductor device may further include an intermediate electrode pattern and a switching pattern. For example, the semiconductor device may include a structure in which the lower electrode pattern 121, the switching pattern, the intermediate electrode pattern, the variable resistance pattern 123, and the upper electrode pattern 125 are sequentially stacked.

In this case, the lower electrode pattern 121, the switching pattern, and the intermediate electrode pattern may configure a selection element. The selection element may be a diode, a PNP diode, a transistor, a vertical transistor, a bipolar junction transistor (BJT), a metal insulator transition (MIT) element, a mixed ionic-electronic conduction (MIEC) element, an ovonic threshold switching (OTS) element, or the like. For example, the switching pattern may include a chalcogenide material.

In addition, the intermediate electrode pattern, the variable resistance pattern 123, and the upper electrode pattern 125 may configure a memory element. Each of the memory element and the selection element may share the intermediate electrode pattern.

The memory cells MC may be arranged in the first direction I and the second direction II. The memory cells MC may be spaced apart from each other by a first interval R1 in the first direction I, and may be spaced apart from each other by a second interval R2 in the second direction II. Here, the second interval R2 may be shorter than the first interval R1. In other words, the memory cells MC may be positioned closer to each other in the second direction II than in the first direction I. In this case, in a process of manufacturing the semiconductor device, the column lines 180 that are spaced apart from each other and extend in the second direction II may be formed by forming a conductive layer by utilizing the memory cells MC positioned relatively close to each other in the second direction II.

The barrier patterns 130 may be positioned on the memory cells MC, respectively. For example, the barrier patterns 130 may be arranged in the first direction I and the second direction II, and may be positioned correspondingly to the memory cells MC. Specifically, each of the barrier patterns 130 may be disposed on a corresponding (e.g., overlapping) one of the memory cells MC. In other words, the barrier patterns 130 may be spaced apart from each other by the first interval R1 in the first direction I, and may be spaced apart from each other by the second interval R2 in the second direction II.

The barrier patterns 130 adjacent to each other in the second direction II may be connected to each other through the column lines 180. For example, the column lines 180 may extend in the second direction II, and may connect the barrier patterns 130 to each other. Specifically, each of the column lines 180 may extend in the second direction II to electrically connect a first plurality of the barrier patterns 130 arranged in the second direction II. Here, the column lines 180 may connect the barrier patterns 130 to each other to surround the barrier patterns 130 in the first direction I and the second direction II, respectively. In other words, the column lines 180 may connect the barrier patterns 130 to each other to cover sidewalls of the barrier patterns 130. For example, each of the column lines 180 may surround a first plurality of the barrier patterns 130 arranged in the second direction II to electrically connect the first plurality of the barrier patterns 130.

A height of each of the barrier patterns 130 may be substantially the same as a height of each of the column lines 180. For example, upper surfaces of the barrier patterns 130 may be positioned at substantially the same level as upper surfaces of the column lines 180. In other words, the column lines 180 may be positioned at substantially the same level as the barrier patterns 130, rather than being positioned on the barrier patterns 130.

The barrier patterns 130 may electrically connect the column lines 180 and the memory cells MC. In addition, the barrier patterns 130 may prevent or reduce damage to the memory cells MC in a manufacturing process of the semiconductor device. The barrier patterns 130 may include a nitride. For example, the barrier patterns 130 may include tungsten silicon nitride (WSiN).

The first liner patterns 140 may cover sidewalls adjacent in the second direction II of the memory cells MC. For example, the first liner patterns 140 may cover sidewalls adjacent in the second direction II of the memory cells MC, and may cover sidewalls adjacent in the second direction II of the row lines 110. Each of the first liner patterns 140 may extend along the row line 110, the lower electrode pattern 121, the variable resistance pattern 123, and the upper electrode pattern 125.

The second liner patterns 160 may cover sidewalls adjacent in the first direction I of the memory cells MC. For example, each of the second liner patterns 160 may extend along the lower electrode pattern 121, the variable resistance pattern 123, and the upper electrode pattern 125. A height of the second liner patterns 160 in the third direction III may be less than a height of the first liner patterns 140 in the third direction III. An upper surface of each of the second liner patterns 160 may be positioned at substantially the same level as an upper surface of each of the first liner patterns 140. Here, the upper surfaces of the first liner patterns 140 and the upper surfaces of the second liner patterns 160 may be in contact with lower surfaces of the column lines 180. The first liner patterns 140 and the second liner patterns 160 may protect the memory cells MC in the process of manufacturing the semiconductor device. At least one of the first liner patterns 140 or the second liner patterns 160 may include a nitride.

The first gap-fill patterns 150 may be positioned between the memory cells MC adjacent in the second direction II, and may have a first width T1. For example, each of the first gap-fill patterns 150 may be positioned between an adjacent pair of the memory cells MC in the second direction II, and may have a first width T1 in the second direction II. Here, the first gap-fill patterns 150 may be positioned on the first liner patterns 140. In other words, the first liner patterns 140 may be positioned between the first gap-fill patterns 150 and the memory cells MC.

The second gap-fill patterns 170 may be positioned between the memory cells MC adjacent in the first direction I, and may have a second width T2. For example, each of the second gap-fill patterns 170 may be positioned between an adjacent pair of the memory cells MC in the first direction I, and may have a second width T2 in the first direction I. Here, the second width T2 may be greater than the first width T1. In addition, the second gap-fill patterns 170 may be positioned on the second liner patterns 160. In other words, the second liner patterns 160 may be positioned between the second gap-fill patterns 170 and the memory cells MC. For example, each of the second liner patterns 160 may be positioned between a corresponding (e.g., contacting) one of the second gap-fill patterns 170 and a corresponding (e.g., contacting) one of the memory cells MC.

At least one of the first gap-fill patterns 150 or the second gap-fill patterns 170 may include a material having an etching selectivity with respect to the first liner patterns 140 and the second liner patterns 160. For example, at least one of the first gap-fill patterns 150 or the second gap-fill patterns 170 may include an oxide.

The third gap-fill patterns 190 may be positioned between the column lines 180 adjacent in the first direction I, and may have a third width T3 in the first direction I. For example, each of the third gap-fill patterns 190 may be positioned between an adjacent pair of the column lines 180 in the first direction I, and thus a second plurality of the barrier patterns 130 that are spaced apart from each other in the first direction I may be electrically disconnected from each other. Here, the third width T3 may be shorter than the second width T2 of the second gap-fill pattern 170 in the first direction I. Here, an upper surface of each of the third gap-fill patterns 190 may be positioned at substantially the same level as the upper surface of each of the column lines 180. For example, a difference between an upper surface of each of the third gap-fill patterns 190 and a corresponding (e.g., abutting) one of the column lines 180 may be not greater than 5%, 3%, or 1% of an average of a height of the third gap-fill pattern 190 and a height of the column line 180. In addition, an upper surface of the column line 180 may be positioned at substantially the same level as an upper surface of the barrier pattern 130. For example, a difference between an upper surface of each of the column lines 180 and a corresponding (e.g., abutting) one of the barrier patterns 130 may be not greater than 5%, 3%, or 1% of an average of a height of the column line 180 and a height of the barrier pattern 130. In other words, the upper surface of each of the third gap-fill patterns 190 may be positioned at substantially the same level as the upper surface of each of the barrier patterns 130 and the upper surface of each of the column lines 180. The third gap-fill patterns 190 may include an insulating material such as an oxide.

The contact vias CT may extend through the first gap-fill patterns 150. An upper surface of each of the contact vias CT may be positioned at substantially the same level as the upper surface of each of the column lines 180. In other words, the upper surface of each of the contact vias CT may be positioned at substantially the same level as the upper surface of each of the barrier patterns 130, the upper surface of each of the third gap-fill patterns 190, and the upper surface of each of the column lines 180. The contact vias CT may include a conductive material such as tungsten.

For reference, although not shown in this drawing, the contact vias CT may be electrically connected to one or more peripheral circuits or the like positioned under the memory cells MC, and may electrically connect the column lines 180 and the peripheral circuits.

According to the structure described above, the memory cells MC may be spaced apart from each other by the first interval R1 in the first direction I, and may be spaced apart from each other by the second interval R2 shorter than the first interval R1 in the second direction II. In addition, the upper surface of each of the column lines 180 and the upper surface of each of the barrier patterns 130 may be positioned at substantially the same level. In this case, a size of the semiconductor device may be reduced, and an integration degree of the semiconductor device may be improved.

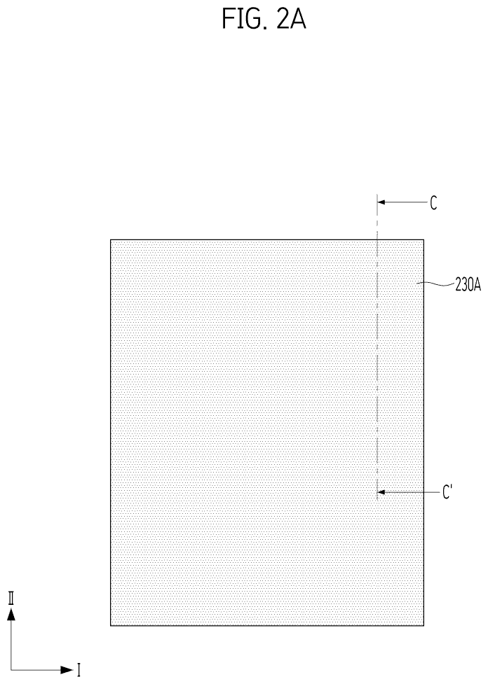

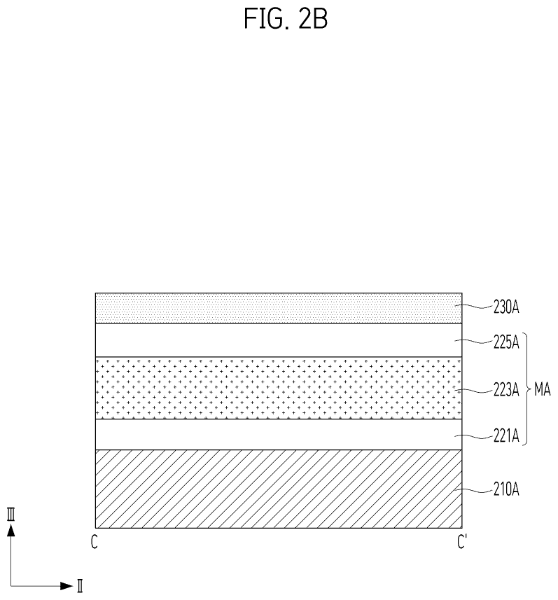

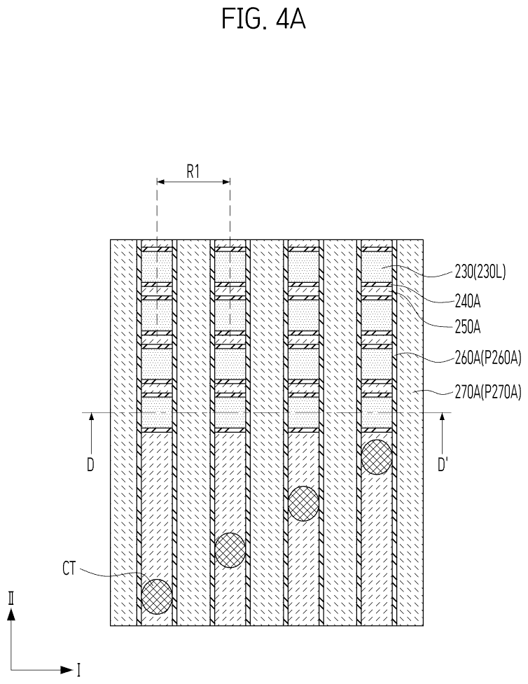

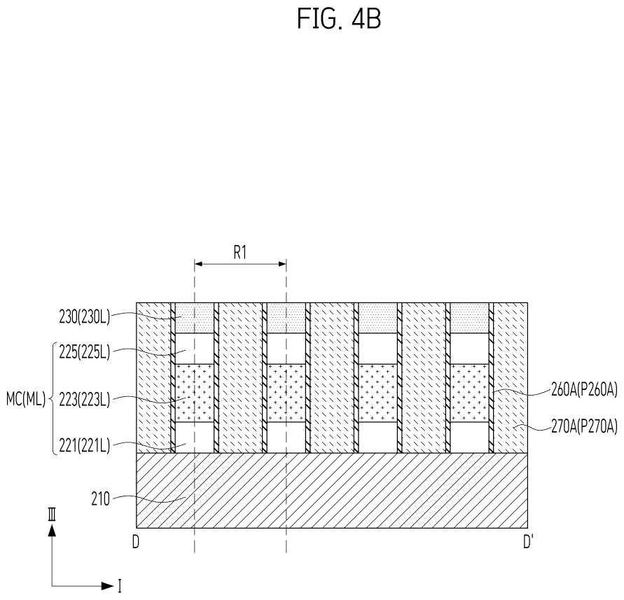

FIGS. 2A, 2B, 3A, 3B, 4A, 4B, 5A, 5B, 5C, 6A, 6B, 6C, 7A, 7B, and 7C are drawings illustrating a method of manufacturing a semiconductor device according to an embodiment of the present disclosure. FIGS. 2A, 3A, 4A, 5A, 6A, and 7A are plan views, and FIGS. 2B, 3B, 5B, 6B, and 7B are cross-sectional views of along lines C-C′ of FIGS. 2A, 3A, 5A, 6A, and 7A, respectively, and FIGS. 4B, 5C, 6C, and 7C are cross-sectional views along lines D-D′ of FIGS. 4A, 5A, 6A, and 7A, respectively. Hereinafter, contents that overlap the above-described contents may be omitted for the interest of brevity.

Referring to FIGS. 2A and 2B, a memory layer MA may be formed on a first conductive layer 210A. For example, the memory layer MA may be formed by sequentially stacking a lower electrode layer 221A, a variable resistance layer 223A, and an upper electrode layer 225A on the first conductive layer 210A. Here, the first conductive layer 210A may include a conductive material such as tungsten.

Subsequently, a barrier layer 230A may be formed on the memory layer MA. Here, the barrier layer 230A may include a nitride. For example, the barrier layer 230A may include tungsten silicon nitride (WSiN).

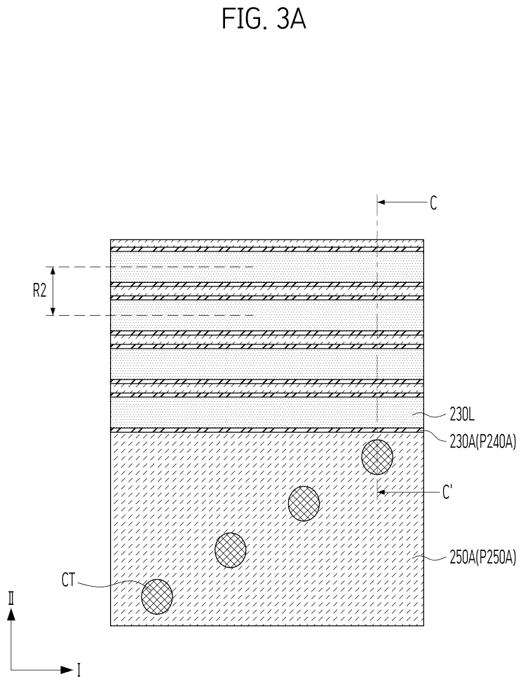

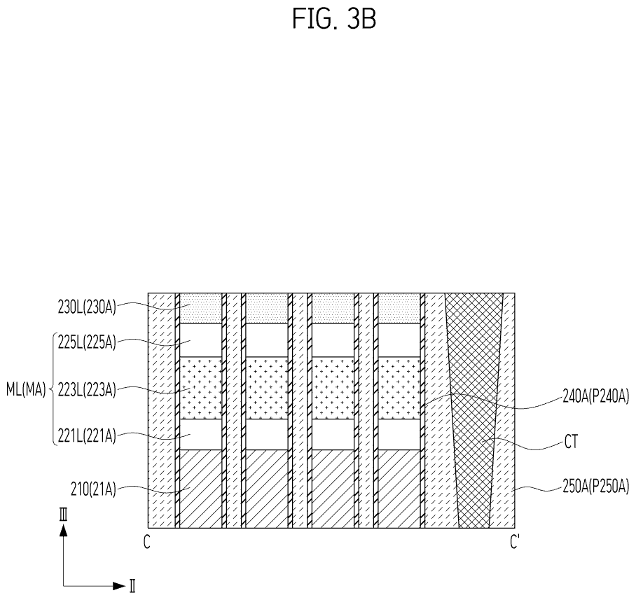

Referring to FIGS. 3A and 3B, barrier lines 230L extending in a first direction I may be formed by etching the barrier layer 230A. Here, the barrier lines 230L may be spaced apart from each other by a second interval R2 in a second direction II crossing the first direction I. For example, center lines of an adjacent pair of the barrier lines 230L in the second direction II may be spaced part from each other by a second interval R2.

Subsequently, memory lines ML extending in the first direction I may be formed by etching the memory layer MA. For example, the memory lines ML including upper electrode lines 225L, variable resistance lines 223L, and lower electrode lines 221L may be formed by sequentially etching the upper electrode layer 225A, the variable resistance layer 223A, and the lower electrode layer 221A. Here, the memory lines ML may be spaced apart from each other by the second interval R2 in the second direction II.

Subsequently, row lines 210 extending in the first direction I may be formed by etching the first conductive layer 210A. Here, each of the row lines 210 may a bit line or a word line.

Subsequently, a preliminary first liner layer P240A covering sidewalls adjacent in the second direction II of the barrier lines 230L and sidewalls adjacent in the second direction II of the memory lines ML may be formed. For example, a preliminary first liner layer P240A may be formed conformally along a profile of the row lines 210, the memory lines ML, and the barrier lines 230L. Here, the preliminary first liner layer P240A may include an insulating material such as a nitride.

Subsequently, a preliminary first gap-fill layer P250A may be formed on the preliminary first liner layer P240A. For example, the preliminary first gap-fill layer P250A may be formed to fill spaces between the barrier lines 230L adjacent in the second direction II and spaces between the memory lines ML adjacent in the second direction II. Specifically, the preliminary first gap-fill layer P250A may be formed to fill spaces each between an adjacent pair of the barrier lines 230L in the second direction II and spaces each between an adjacent pair of the memory lines ML in the second direction II. Here, the preliminary first gap-fill layer P250A may include a material having an etching selectivity with respect to the preliminary first liner layer P240A. For example, the preliminary first gap-fill layer P250A may include an insulating material such as an oxide.

Subsequently, the preliminary first gap-fill layer P250A and the preliminary first liner layer P240A may be etched so that the barrier lines 230L are exposed. For example, the preliminary first gap-fill layer P250A and the preliminary first liner layer P240A may be planarized so that upper surfaces of the barrier lines 230L are exposed. Here, the preliminary first gap-fill layer P250A may be separated into first gap-fill layers 250A, and the preliminary first liner layer P240A may be separated into first liner layers 240A. Specifically, each of the first gap-fill layers 250A may be formed between an adjacent pair of the barrier lines 230L in the second direction II and between an adjacent pair of the memory lines ML in the second direction II.

Subsequently, contact vias CT extending through the first gap-fill layers 250A may be formed. For example, the contact vias CT may be formed so as to pass through the first gap-fill layer 250A. The contact vias CT may be formed as many as the number of row lines 210. However, embodiments of the present disclosure are not limited thereto, and the number of contact vias CT and the number of row lines 210 may be different. The contact vias CT may include a conductive material such as tungsten.

Referring to FIGS. 4A and 4B, barrier patterns 230 arranged in the first direction I and the second direction II may be formed by etching the barrier lines 230L. Here, the barrier patterns 230 may be spaced apart from each other by a first interval R1 in the first direction I. Here, the first interval R1 may be greater than the second interval R2.

Subsequently, memory cells MC arranged in the first direction I and the second direction II may be formed by etching the memory lines ML. For example, the memory cells MC including upper electrode patterns 225, variable resistance patterns 223, and lower electrode patterns 221 may be formed by etching the upper electrode lines 225L, the variable resistance lines 223L, and the lower electrode lines 221L. Here, the memory cells MC may be spaced apart from each other by the first interval R1 in the first direction I.

Subsequently, a preliminary second liner layer P260A covering sidewalls adjacent in the first direction I of the barrier lines 230L and sidewalls adjacent in the first direction I of the memory cells MC may be formed. For example, the preliminary second liner layer P260A may be formed conformally along a profile of the memory cells MC and the barrier patterns 230. Here, the preliminary second liner layer P260A may include an insulating material such as a nitride.

Subsequently, a preliminary second gap-fill layer P270A may be formed on the preliminary second liner layer P260A. For example, the preliminary second gap-fill layer P270A may be formed to fill spaces between the barrier patterns 230 adjacent in the first direction I and spaces between the memory cells MC adjacent in the first direction I. Specifically, the preliminary second gap-fill layer P270A may be formed to fill spaces each between an adjacent pair of the barrier patterns 230 in the first direction I and fill spaces each between an adjacent pair of the memory cells MC in the first direction I. Here, the preliminary second gap-fill layer P270A may include a material having an etching selectivity with respect to the preliminary second liner layer P260A. For example, the preliminary second gap-fill layer P270A may include an insulating material such as an oxide.

Subsequently, the preliminary second gap-fill layer P270A and the preliminary second liner layer P260A may be etched so that the barrier patterns 230 are exposed. For example, the preliminary second gap-fill layer P270A and the preliminary second liner layer P260A may be planarized so that upper surfaces of the barrier patterns 230 are exposed. Here, the preliminary second gap-fill layer P270A may be separated into second gap-fill layers 270A, and the preliminary second liner layer P260A may be separated into second liner layers 260A. Specifically, each of the second gap-fill layers 270A may be formed between an adjacent pair of the barrier patterns 230 in the first direction I and between an adjacent pair of the memory cells MC in the first direction I.

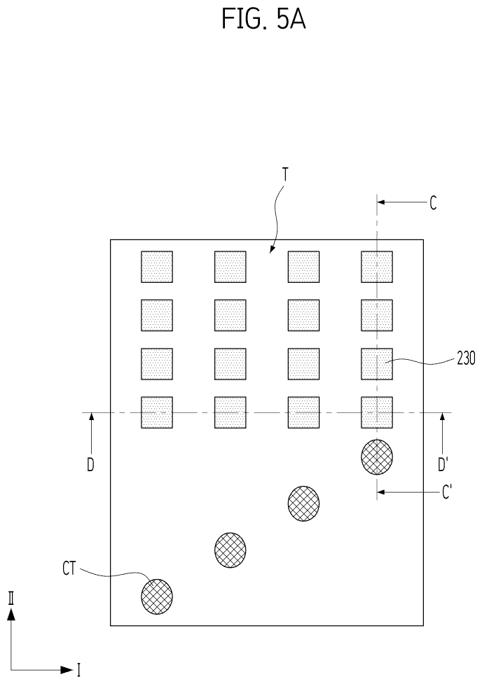

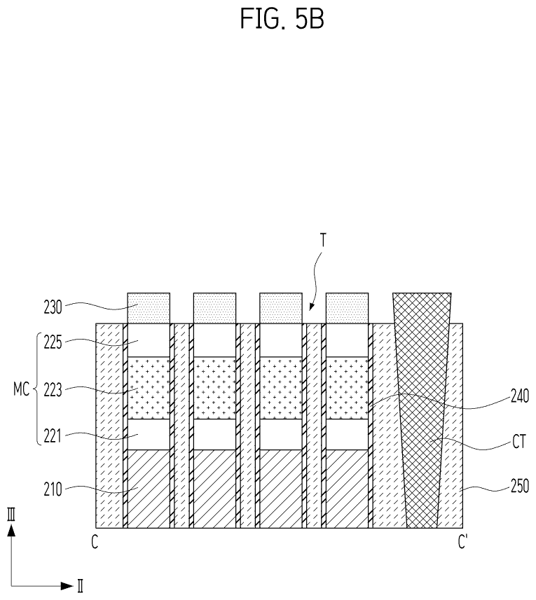

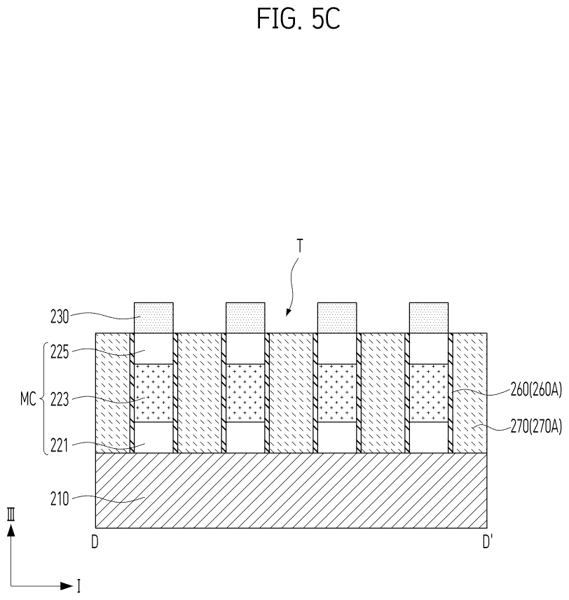

Referring to FIGS. 5A to 5C, a trench T exposing sidewalls of the barrier patterns 230 may be formed. For example, the first gap-fill layers 250A and the second gap-fill layers 270A may be selectively etched. Subsequently, the trench T may be formed by selectively etching the first liner layers 240A and the second liner layers 260A. However, embodiments of the present disclosure are not limited thereto, after etching the first liner layers 240A and the second liner layers 260A first, the first gap-fill layers 250A and the second gap-fill layers 270A may be etched. Here, the trench T may expose sidewalls of the contact vias CT.

Accordingly, the first liner layers 240A may become first liner patterns 240 covering sidewalls adjacent in the second direction II of the memory cells MC, and the second liner layers 260A may become second liner patterns 260 covering sidewalls adjacent in the first direction I of the memory cells MC. The first gap-fill layers 250A may become first gap-fill patterns 250 filling spaces between the memory cells MC adjacent in the second direction II, and the second gap-fill layers 270A may become second gap-fill patterns 270 filling spaces between the memory cells MC adjacent in the first direction I. Here, upper surfaces of the first liner patterns 240, the second liner patterns 260, the first gap-fill patterns 250, and the second gap-fill patterns 270 may be positioned at substantially the same level.

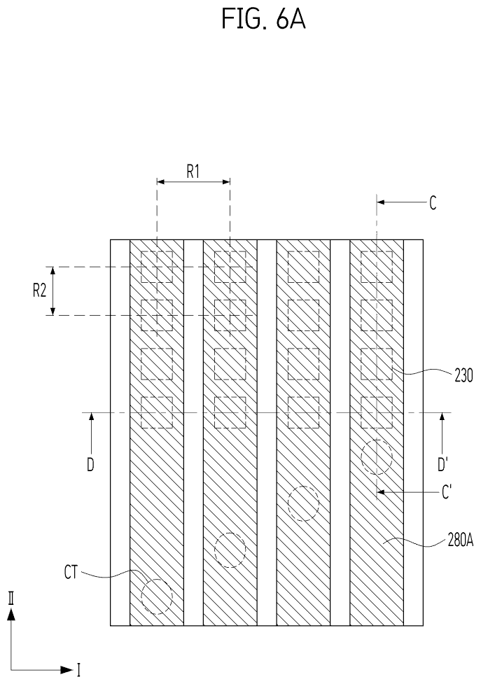

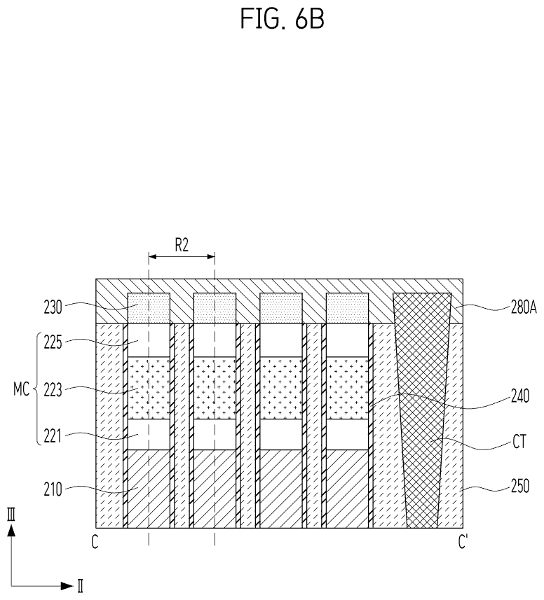

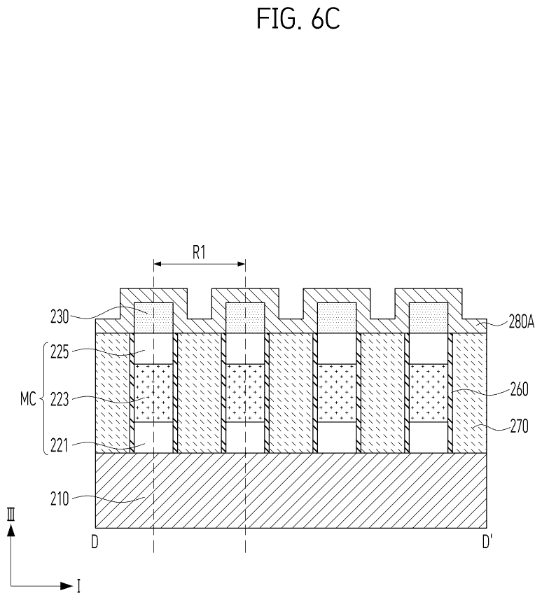

Referring to FIGS. 6A and 6B, a second conductive layer 280A may be formed in the trench T. For example, the second conductive layer 280A may be formed to fill spaces between the barrier patterns 230 adjacent in the second direction II. Here, the second conductive layer 280A may partially fill spaces between the barrier patterns 230 adjacent in the first direction I. In other words, because the second interval R2 in the second direction II is shorter than the first interval R1 in the first direction I, the second conductive layer 280A may be formed so as to entirely fill spaces each between an adjacent pair of the barrier patterns 230 in the second direction II and so as to partially fill spaces each between an adjacent pair of the barrier patterns 230 in the first direction I. In this case, the second conductive layer 280A may have a wave shape in the first direction I, and may have a substantially flat upper surface in the second direction II. In the embodiment of FIGS. 6A, 6B, and 6C, center lines of an adjacent pair of the barrier patterns 230 in the first direction I may be spaced part from each other by a first interval R1, and center lines of an adjacent pair of the barrier patterns 230 in the second direction II may be spaced part from each other by a second interval R2. However, embodiments of the present disclosure are not limited thereto. In some embodiments, the first interval R1 may be defined as a distance between facing sidewalls of an adjacent pair of the barrier patterns 230 in the first direction I, and the second interval R2 may be defined as a distance between facing sidewalls of an adjacent pair of the barrier patterns 230 in the second direction II. The second conductive layer 280A may include a conductive material such as tungsten.

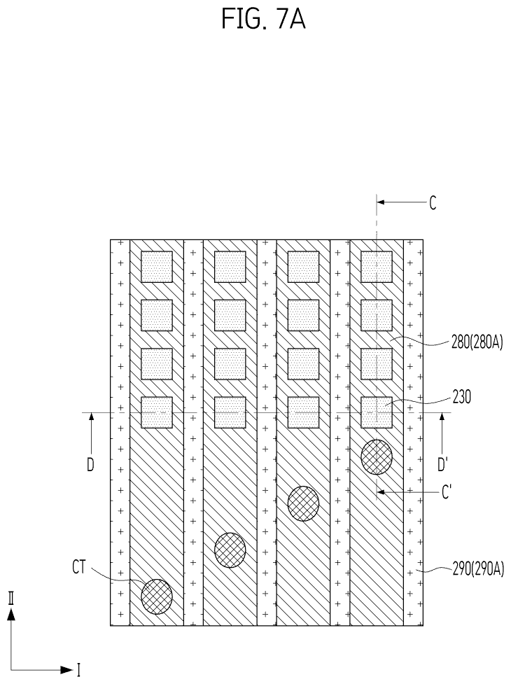

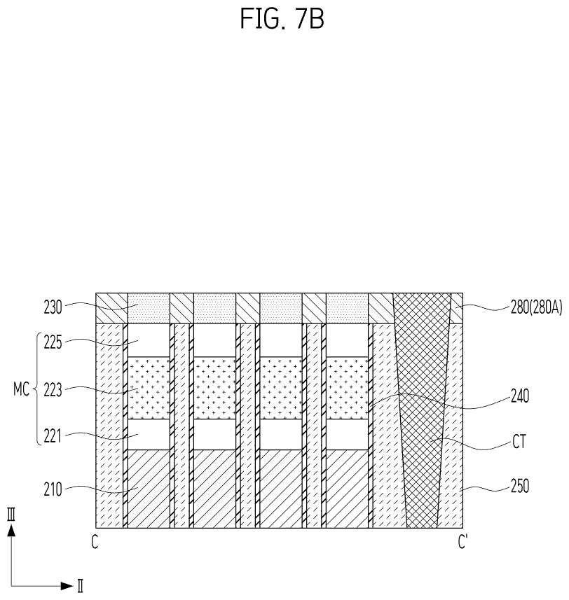

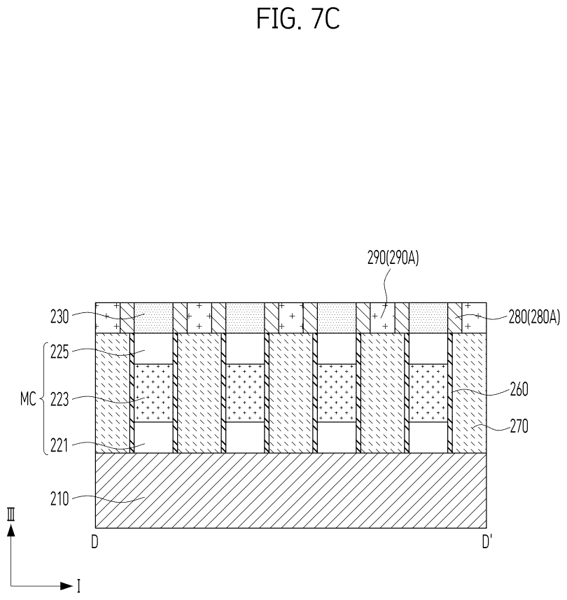

Referring to FIGS. 7A to 7C, column lines 280 connecting the barrier patterns 230 in the second direction II may be formed by etching the second conductive layer 280A. Specifically, each of the column lines 280 may be formed to connect a plurality of the barrier patterns 230 that are arranged in the second direction II. For example, the column lines 280 may be formed by etching first portions of the second conductive layer 280A each formed between an adjacent pair of the barrier patterns 230 in the first direction I and etching second portions of the second conductive layer 280A on the barrier patterns 230 so that the upper surfaces of the barrier patterns 230 are exposed. Here, the column lines 280 may remain on sidewalls adjacent in the first direction I of the barrier patterns 230.

The column lines 280 may connect the barrier patterns 230 and the contact vias CT in the second direction II. In other words, the column line 280 may connect the barrier patterns 230 and the contact via CT adjacent in the second direction II to each other. Here, each of the column lines 280 may be a word line or a bit line.

Subsequently, third gap-fill patterns 290 may be formed between the barrier patterns 230 adjacent in the first direction I. For example, the third gap-fill patterns 290 each may be formed between an adjacent pair of the column lines 280 in the first direction I. First, a third gap-fill layer 290A may be formed on and between the column lines 280 adjacent in the first direction I. Subsequently, the third gap-fill layer 290A may be etched so that upper surfaces of the column lines 280 are exposed. Here, the third gap-fill layer 290A may be separated into the third gap-fill patterns 290. The third gap-fill patterns 290 may include an insulating material such as an oxide.

When column lines are formed on barrier patterns in a conventional semiconductor device, a size of the semiconductor device increases. In this case, an integration degree of the semiconductor device may not be sufficiently improved. According to an embodiment of the present disclosure, the column lines 280 may be formed so that the upper surfaces of the column lines 280 are positioned at substantially the same level as the upper surfaces of the barrier patterns 230. For example, the second conductive layer 280A may be formed so as to fill spaces between the barrier patterns 230 adjacent in the second direction II and so as to partially fill spaces between the barrier patterns 230 adjacent in the first direction I, by utilizing a fact that the second interval R2 in the second direction II is shorter than the first interval R1 in the first direction I. Subsequently, the column lines 280 that are spaced apart from each other in the first direction I and extend in the second direction II may be formed, by etching the second conductive layer 280A so that upper surfaces of the barrier patterns 230 are exposed. Therefore, according to an embodiment of the present disclosure, because the column lines 280 may be formed at substantially the same level as the barrier patterns 230, the integration degree of the semiconductor device may be improved compared to the conventional semiconductor device.

When forming column lines on barrier patterns in a conventional semiconductor device, the column lines are considered so as to form memory cells by etching the memory lines. For example, penetration of etchant used when etching the memory lines may not be smoothly performed or a bias required when etching the memory lines may not be appropriately applied due to the column lines formed on the barrier patterns. For example, a plasma process may be performed when etching the memory lines, and the bias required for this process may not be appropriately applied. In such a case, a more etching time is required or a greater bias is required to be applied so as to etch the memory lines. Therefore, a manufacturing time, a manufacturing cost, or the like for the conventional semiconductor device may increase.

According to an embodiment of the present disclosure, before forming column lines 280, the memory cells MC may be formed. In this case, because the column lines 280 are not formed on the barrier patterns 230, penetration of etchant used when etching the memory lines ML may be smoothly performed, and the bias required when etching the memory lines ML may be applied appropriately. Therefore, a manufacturing time, a manufacturing cost, or the like in a manufacturing process of the semiconductor device according to an embodiment of the present disclosure may be reduced compared to the conventional semiconductor device.

According to the manufacturing method described above, after forming the memory cells MC, the column lines 280 may be formed. Here, the column lines 280 may be formed by utilizing the fact that the second interval R2 of the memory cells MC is shorter than the first interval R1. In this case, the integration degree of the semiconductor device may be improved, and the manufacturing time and the manufacturing cost in the manufacturing process of the semiconductor device may be reduced.

Although some embodiments of the present disclosure have been described with reference to the accompanying drawings, various embodiments of the present disclosure are not limited to the above-described embodiments. Various forms of substitution, modification, and change of the embodiments will be possible by those skilled in the art to which the present disclosure belongs, and these also belong to embodiments of the present disclosure.

What is claimed is:

1. A semiconductor device comprising:
row lines extending in a first direction;
column lines positioned on the row lines, and extending in a second direction that crosses the first direction; and
memory cells positioned between the row lines and the column lines, respectively, and spaced apart from each other by a first interval in the first direction and spaced apart from each other by a second interval in the second direction, the second interval being shorter than the first interval.

2. The semiconductor device of claim 1, further comprising:
barrier patterns positioned on the memory cells, respectively.

3. The semiconductor device of claim 2, wherein each of the column lines extends in the second direction to electrically connect a first plurality of the barrier patterns, the first plurality of the barrier patterns being arranged in the second direction.

4. The semiconductor device of claim 3, wherein a second plurality of the barrier patterns are spaced apart from each other in the first direction.

5. The semiconductor device of claim 4, wherein the second plurality of the barrier patterns are electrically disconnected from each other.

6. The semiconductor device of claim 2, wherein each of the column lines surrounds a first plurality of the barrier patterns arranged in the second direction to electrically connect the first plurality of the barrier patterns.

7. The semiconductor device of claim 2, wherein an upper surface of each of the column lines is positioned at substantially the same level as an upper surface of a corresponding one of the barrier patterns.

8. The semiconductor device of claim 2, wherein the barrier patterns include nitride.

9. The semiconductor device of claim 8, wherein the barrier patterns include tungsten silicon nitride.

10. The semiconductor device of claim 1, further comprising:
second gap-fill patterns each positioned between an adjacent pair of the memory cells in the first direction; and
third gap-fill patterns each positioned between an adjacent pair of the column lines in the first direction, each of the third gap-fill patterns having a width shorter than that of each of the second gap-fill patterns.

11. The semiconductor device of claim 10, wherein an upper surface of each of the third gap-fill patterns is positioned at substantially the same level as an upper surface of a corresponding one of the column lines.

12. A semiconductor device comprising:
row lines extending in a first direction;
memory cells positioned on the row lines;
barrier patterns positioned on the memory cells, respectively; and
column lines extending in a second direction that crosses the first direction, and connecting the barrier patterns,
wherein the memory cells are spaced apart from each other by a first interval in the first direction and spaced apart from each other by a second interval in the second direction, the second interval being shorter than the first interval.

13. The semiconductor device of claim 12, wherein each of the column lines extends in the second direction to connect a first plurality of the barrier patterns, the first plurality of the barrier patterns being arranged in the second direction.

14. The semiconductor device of claim 13, wherein a second plurality of the barrier patterns are spaced apart from each other in the first direction.

15. The semiconductor device of claim 14, wherein the second plurality of the barrier patterns are electrically disconnected from each other.

16. The semiconductor device of claim 13, wherein each of the column lines surrounds the first plurality of the barrier patterns arranged in the second direction to connect the first plurality of the barrier patterns.

17. The semiconductor device of claim 13, wherein an upper surface of each of the column lines is positioned at substantially the same level as an upper surface of a corresponding one of the barrier patterns.

18. The semiconductor device of claim 12, wherein the barrier patterns include a nitride.

19. The semiconductor device of claim 18, wherein the barrier patterns include tungsten silicon nitride.

20. The semiconductor device of claim 12, further comprising:
second gap-fill patterns each positioned between an adjacent pair of the memory cells in the first direction; and
third gap-fill patterns each positioned between an adjacent pair of the column lines in the first direction, each of the third gap-fill patterns having a width shorter than that of each of the second gap-fill patterns.

21. The semiconductor device of claim 20, wherein an upper surface of each of the third gap-fill patterns is positioned at substantially the same level as an upper surface of each of the column lines.

22. A method of manufacturing a semiconductor device, the method comprising:
forming a memory layer on a first conductive layer;
forming memory lines that extend in a first direction and are spaced apart from each other by a second interval in a second direction by etching the memory layer, the second direction crossing the first direction;
forming row lines that extend in the first direction by etching the first conductive layer;
forming memory cells arranged in the first direction and the second direction and spaced apart from each other by a first interval in the first direction by etching the memory lines, the first interval being greater than the second interval; and
forming column lines that extend in the second direction on the memory cells.

23. The method of claim 22, further comprising:
forming a barrier layer on the memory layer;
forming barrier lines that extend in the first direction by etching the barrier layer;
forming first gap-fill layers each between an adjacent pair of the barrier lines in the second direction and between an adjacent pair of the memory lines in the second direction;
forming barrier patterns arranged in the first direction and the second direction by etching the barrier lines;
forming second gap-fill layers each between an adjacent pair of the barrier patterns in the first direction and between an adjacent pair of the memory cells in the first direction;
forming a trench that exposes sidewalls of the barrier patterns by etching the first gap-fill layers and the second gap-fill layers;
forming a second conductive layer in the trench; and
forming the column lines each connecting a first plurality of the barrier patterns by etching the second conductive layer, the first plurality of the barrier patterns being arranged in the second direction.

24. The method of claim 23, wherein forming the trench comprises selectively etching the first gap-fill layers and the second gap-fill layers.

25. The method of claim 23, wherein the second conductive layer partially fills spaces each between an adjacent pair of the barrier patterns in the first direction and entirely fills spaces each between an adjacent pair of the barrier patterns adjacent in the second direction.

26. The method of claim 23, wherein forming the column lines etches first portions of the second conductive layer each positioned between an adjacent pair of the barrier patterns in the first direction, and etches second portions of the second conductive layer on the barrier patterns so that upper surfaces of the barrier patterns are exposed.

27. The method of claim 26, further comprising:
forming third gap-fill patterns each between the adjacent pair of the barrier patterns in the first direction.
